(19) United States
(12) Patent Application Publication
(10) Pub. No.: US 2012/0049260 A1
(43) Pub. Date: Mar. 1, 2012

(54) METHOD FOR FORMING CAPACITOR AND SEMICONDUCTOR DEVICE USING THE SAME

(75) Inventors: Hyun Seok KIM, Icheon-si (KR); Jun Ho LEE, Seongnam-si (KR); Boo Ho JUNG, Icheon-si (KR); Sun Ki CHO, Icheon-si (KR); Yang Hee KIM, Icheon-si (KR); Young Won KIM, Icheon-si (KR)

(73) Assignee: HYNIX SEMICONDUCTOR INC., Icheon-si (KR)

(21) Appl. No.: 13/217,341

(22) Filed: Aug. 25, 2011

(30) Foreign Application Priority Data
Aug. 26, 2010 (KR) 10-2010-0083052

(51) Int. Cl. H01L 27/06; H01L 21/8234

(52) U.S. Cl. 257/300; 438/241; 257/E27.016; 257/E21.616

(57) ABSTRACT

A semiconductor device includes a MOS capacitor including a gate, a source, and a drain, a cylinder capacitor including a top electrode, a dielectric layer, and a bottom electrode, and a metal interconnection that connects the gate to the bottom electrode.

### CROSS-REFERENCES TO RELATED APPLICATIONS

The present application claims priority under 35 U.S.C 119(a) to Korean Application No. 10-2010-0083052, filed on Aug. 26, 2010, in the Korean intellectual property Office, which is incorporated herein by reference in its entirety.

### BACKGROUND

Capacitors are utilized in the semiconductor devices for stable supply of voltage and stabilization of transmitted and received signals. Decoupling capacitors are mainly used for effectively preventing fluctuations in the voltage and signal strengths due to noise. A decoupling capacitor is usually connected between an internal circuit and an interconnection for voltage supply or signal transmission as a temporary current source to remove noise. A decoupling capacitor therefore is configured to supply current necessary for the internal circuit operation, thereby substantially preventing noise and voltage drop by substantially preventing a sudden flow of current from a voltage supply source to the internal circuit.

FIG. 1 is an equivalent circuit diagram of a known decoupling capacitor for removing noise of a power supply voltage according to the conventional art.

Referring to FIG. 1, a semiconductor device includes first and second capacitors CP1, CP2 connected in series between a power supply voltage VDD and a ground voltage VSS, and a MOS capacitor MOSCP positioned between the power supply voltage VDD and the ground voltage VSS, thereby attenuating noise in the power supply voltage VDD.

However, in such a conventional structure as shown in FIG. 1, there are physical connections (besides electrical connections) between the first and second capacitors CP1, CP2 serially connected to each other and the MOS capacitor MOSCP. Resistance increases when the power supply voltage VDD having a high frequency component is applied. Then, the high frequency component of the power supply voltage VDD may not be filtered, and it will lead to reduction in the efficiency of high frequency noise attenuation.

Furthermore, gaps exist between the electrodes of the first and second capacitors CP1, CP2 to which the power supply voltage VDD is applied and the electrodes of the first and second capacitors CP1, CP2 to which the ground voltage VSS is applied due to the limitations imposed by the processing design rule, and this leads to wasted areas in the circuit.

### SUMMARY

An embodiment of the present invention relates to a method for forming a capacitor and a semiconductor device using the same, which can improve noise attenuation efficiency of a decoupling capacitor by reducing resistance of an interconnection for connecting the decoupling capacitor to a power supply voltage.

In an embodiment, a semiconductor device includes: a MOS capacitor including a gate, a source, and a drain; a cylinder capacitor including a top electrode, a dielectric layer, and a bottom electrode; and a metal interconnection that connects the gate to the bottom electrode.

A method for forming a capacitor according to an embodiment of the present invention includes: forming a first MOS capacitor including a first gate and a first source/drain on a semiconductor substrate; forming a second MOS capacitor including a second gate and a second source/drain on the semiconductor substrate; forming an interlayer dielectric layer above the first and second MOS capacitors; forming a metal interconnection by passing through the interlayer dielectric layer; and forming cylinder capacitors connected to the first and second MOS capacitors through the metal interconnection after forming the metal interconnection.

In an embodiment, a semiconductor device includes: a first metal interconnection connected to a first gate of a first MOS capacitor; a second metal interconnection connected to a second gate of a second MOS capacitor; a first cylinder capacitor including a first bottom electrode connected to the first metal interconnection; and a second cylinder capacitor including a second bottom electrode connected to the second metal interconnection.

### BRIEF DESCRIPTION OF THE DRAWINGS

The above and other aspects, features and other advantages will be more clearly understood from the following detailed description taken in conjunction with the accompanying drawings, in which:

FIG. 1 is an equivalent circuit diagram of a known decoupling capacitor for removing noise of a power supply voltage according to the conventional art;

FIG. 2 is a cross-sectional view illustrating a method for fabricating a semiconductor device according to an embodiment;

FIG. 3 is an equivalent circuit diagram of a semiconductor device according to an embodiment;

FIG. 4 is a graph illustrating the characteristics of capacitors when the same capacitance is realized according to an embodiment and the conventional art;

FIG. 5 is a graph illustrating the characteristics of capacitors when semiconductor devices are realized with the same area according to an embodiment and the conventional art; and

FIG. 6 is a diagram illustrating the three-dimensional structure of a semiconductor device according to an embodiment.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

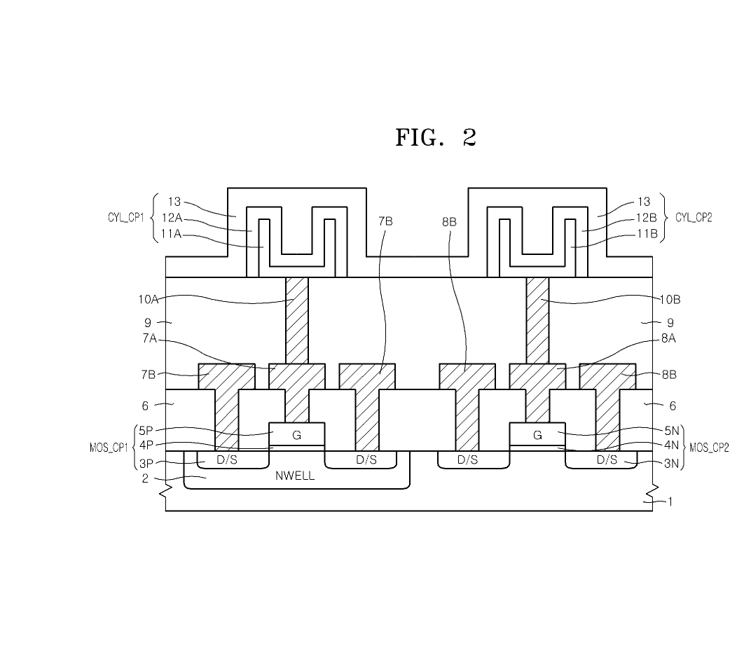

FIG. 2 is a cross-sectional view related to fabricating a semiconductor device according to an embodiment of the present invention.

Referring to FIG. 2, the semiconductor device includes the first and second MOS capacitors MOS_CP1, MOS_CP2, the first and second metal interconnections 10A, 10B, and the first and second cylinder capacitors CYL_CP1, CYL_CP2.

The first MOS capacitor MOS_CP1 includes a first gate 5P and first source/drains 3P.

According to an embodiment of the present invention, the first MOS capacitor MOS_CP1 is formed by, inter alia, forming an N-well region 2 in a semiconductor substrate 1, forming the first gate 5P including a gate oxide layer 4P on the N-well region 2, and forming the first source/drains 3P by implanting impurity ions into the N-well region 2 excluding the region of the first gate 5P. An insulation layer 6 of silicon oxide is formed over the first gate 5P and the first source/drains 3P to have contact holes formed therein. A first interconnection 7A is formed by filling the contact hole formed over the first gate 5P, and second interconnections 7B are filled in the contact holes formed over the first source/drains 3P to connect the first source/drains 3P to the power supply voltage VDD. The first MOS capacitor MOS_CP1 is a PMOS transistor.

The second MOS capacitor MOS_CP2 includes a second gate 5N and second source/drains 3N.

According to an embodiment of the present invention, the second MOS capacitor MOS_CP2 is formed by, inter alia, forming the second gate 5N including a gate oxide layer 4N on the semiconductor substrate 1, and forming the second source/drains 3N by implanting impurity ions into the semiconductor substrate 1 excluding the region of the second gate 5N. The insulation layer 6 of silicon oxide is formed over the second gate 5N and the second source/drains 3N to have contact holes formed therein. A third interconnection 8A is formed by filling a contact hole formed over the second gate 5N, and a fourth interconnection 8B is filled in the contact holes formed over the second source/drains 3N to connect the second source/drains 3N to the ground voltage VSS. The second MOS capacitor MOS_CP2 is an NMOS transistor.

An interlayer dielectric layer 9 is formed above the first and second MOS capacitors MOS_CP1, MOS_CP2 using, for example, silicon oxide.

A first metal interconnection 10A is connected to the first interconnection 7A, which is connected to the first gate 5P, through the interlayer dielectric layer 9. The first metal interconnection 10A is connected, for example, to the ground voltage VSS to apply the ground voltage VSS to the first gate 5P assuming that the first MOS capacitor MOS_CP1 is a PMOS capacitor.

A second metal interconnection 10B is connected to the second interconnection 8A, which is connected to the second gate 5N, through the interlayer dielectric layer 9. The second metal interconnection 10B is connected, for example, to the power supply voltage VDD to apply the power supply voltage VDD to the second gate 5N assuming that the second MOS capacitor MOS_CP2 is an NMOS capacitor.

The first cylinder capacitor CYL_CP1 includes a first bottom electrode 11A, a first dielectric layer 12A, and a top electrode 13.

According to an embodiment of the present invention, the first cylinder capacitor CYL_CP1 is formed by, inter alia, forming the first bottom electrode 11A of, for example, polysilicon on the first metal interconnection 10A, forming the first dielectric layer 12A of, for example, silicon oxide on the first bottom electrode 11A, and forming the top electrode 13 on the first dielectric layer 12A. The first metal interconnection 10A is connected to the first bottom electrode 11A, so that the ground voltage VSS is applied to the first bottom electrode 11A.

The second cylinder capacitor CYL_CP2 includes a second bottom electrode 11B, a second dielectric layer 12B, and the top electrode 13.

According to an embodiment of the present invention, the second cylinder capacitor CYL_CP2 is formed by, inter alia, forming the second bottom electrode 11B of, for example, polysilicon on the second metal interconnection 10B, forming the second dielectric layer 12B of, for example, silicon oxide on the second bottom electrode 11B, and forming the top electrode 13 on the second dielectric layer 12B. The second metal interconnection 10B is connected to the second bottom electrode 11B, so that the power supply voltage VDD is applied to the second bottom electrode 11B.

The first and second cylinder capacitors CYL_CP1, CYL_CP2 are connected to each other in series through the top electrode 13.

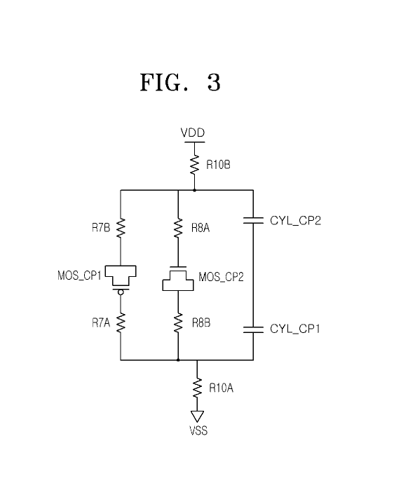

FIG. 3 is an equivalent circuit diagram of the semiconductor device according to an embodiment of the present invention.

Referring to FIG. 3, the power supply voltage VDD can be transferred directly to the first and second MOS capacitors MOS_CP1, MOS_CP2 and the first and second cylinder capacitors CYL_CP1, CYL_CP2, such that the high frequency noise in the power supply voltage VDD is transferred to the ground voltage VSS, resulting in the attenuation of the high frequency noise.

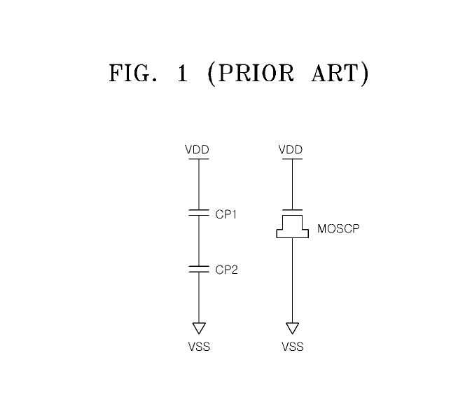

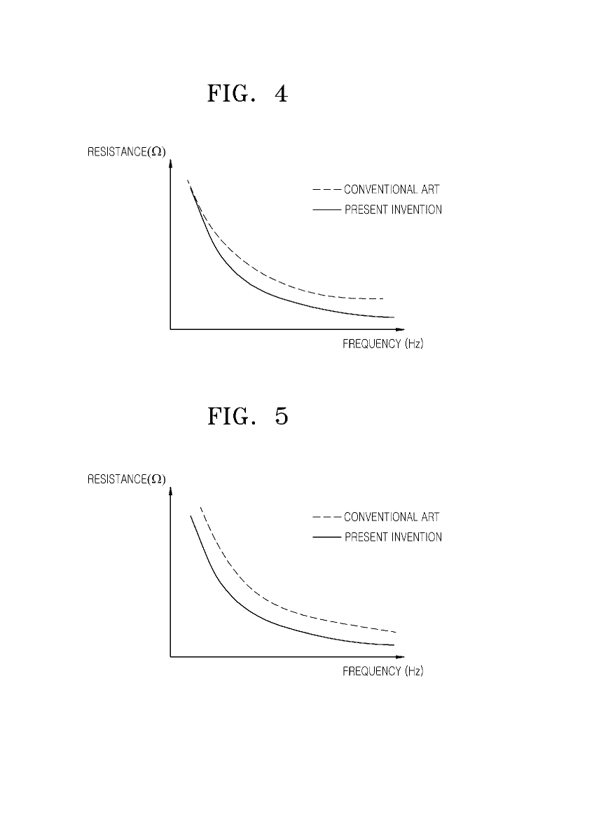

FIG. 4 is a graph related to comparing the characteristics of capacitors of same capacitance between an embodiment of the present invention and the conventional art such as that shown in FIG. 1.

Referring to FIG. 4, it can be understood that the resistance to frequency characteristics of the semiconductor device according to an embodiment of the present invention is much improved over the conventional art. The rate of decreasing resistance values with increasing frequency according to an embodiment of the present invention (see the solid line curve in FIG. 4) is superior than those provided by the conventional art (see the dotted line curve in FIG. 4), so that the noise attenuation efficiency of the high frequency power supply voltage VDD is improved according to an embodiment of the present invention.

FIG. 5 is a graph related to comparing the characteristics of the capacitors in semiconductor devices formed in their respective areas of same size between an embodiment of the present invention and the conventional art such as that shown in FIG. 1.

Referring to FIG. 5, it can be readily understood that resistance values of the semiconductor device according to an embodiment are lower in all frequency range than that of the conventional art, although the semiconductor devices are formed in their respective areas of same size, so that the noise attenuation efficiency of the power supply voltage VDD is improved according to an embodiment of the present invention.

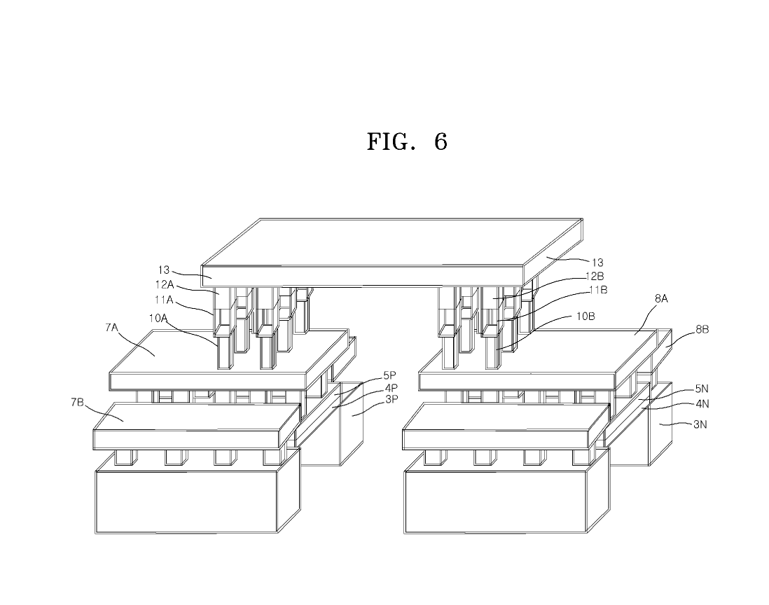

FIG. 6 illustrates the three-dimensional structure of the semiconductor device according to an embodiment of the present invention.

Referring to FIG. 6, in the semiconductor device with the three-dimensional structure according to an embodiment of present invention, the first and second MOS capacitors MOS_CP1 (i.e., 3P, 4P, 5P in FIG. 6), MOS_CP2 (i.e., 3N, 4N, 5N in FIG. 6) are connected to the first and second cylinder capacitors CYL_CP1 (i.e., 11A, 12A, 13 in FIG. 6), CYL_CP2 (i.e., 11B, 12B, 13 in FIG. 6) through the first and second metal interconnections 10A, 10B, respectively, so that it is possible to attenuate the noise of the high frequency power supply voltage VDD.

As described above, when stacking the first and second cylinder capacitors CYL_CP1, CYL_CP2 and the first and second MOS capacitors MOS_CP1, MOS_CP2 in order to attenuate the noise of the power supply voltage VDD of the semiconductor device, the capacitors are separated into the first MOS capacitor MOS_CP1 (e.g., a PMOS-type capacitor) and the second MOS capacitor MOS_CP2 (e.g., an NMOS-type capacitor), and the power supply voltage VDD is directly applied to the first and second cylinder capacitors CYL_CP1, CYL_CP2 and the first and second MOS capacitors MOS_CP1, MOS_CP2 through the metal interconnections 10A, 10B, so that it is possible to reduce an equivalent series resistance value. Consequently, the power supply voltage VDD can be accurately transferred to the first and second cylinder capacitors CYL_CP1, CYL_CP2 and the first and second MOS capacitors MOS_CP1, MOS_CP2, so that it is possible to improve the noise attenuation efficiency of the power supply voltage VDD.

Furthermore, since electrodes receiving the power supply voltage VDD and electrodes receiving the ground voltage VSS are integrated in the first and second cylinder capacitors CYL_CP1, CYL_CP2, a process design rule is meaningless, resulting in a reduction in a semiconductor chip area.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A decoupling capacitor unit in a semiconductor device comprising:
a first capacitor connected between a power supply voltage source and a ground voltage source;
a second capacitor connected between the power supply voltage source and the ground voltage source; and
first and second cylinder capacitors connected in series between the power supply voltage source and the ground voltage source.

2. The decoupling capacitor unit of claim 1, wherein the first capacitor is a PMOS capacitor and the second capacitor is an NMOS capacitor.

3. The decoupling capacitor unit of claim 2, wherein the PMOS capacitor is formed over a N-well in a semiconductor substrate, the PMOS capacitor comprising:
a gate formed over the N-well and coupled to the ground voltage;
a source formed in the N-well and coupled to the power supply voltage; and
a drain formed in the N-well and coupled to the power supply voltage.

4. The decoupling capacitor unit of claim 3 further comprising:
a gate oxide layer formed between the gate of the PMOS capacitor and the N-well in the semiconductor substrate.

5. The decoupling capacitor unit of claim 3, wherein the first cylinder capacitor comprises:
a first bottom electrode connected to the gate of the PMOS capacitor;
a first dielectric layer formed over the first bottom electrode; and
a top electrode formed over the first dielectric layer, wherein the first and second cylinder capacitors are connected in series via the top electrode.

6. The decoupling capacitor unit of claim 5, further comprising:
a first metal interconnection configured to connect the first bottom electrode and the gate of the PMOS capacitor.

7. The decoupling capacitor unit of claim 2, wherein the NMOS capacitor is formed over a semiconductor substrate, the NMOS capacitor comprising:
a gate formed over the semiconductor substrate and coupled to the power supply voltage;
a source formed in the semiconductor substrate and coupled to the ground voltage; and
a drain formed in the semiconductor substrate and coupled to the ground voltage.

8. The decoupling capacitor unit of claim 7 further comprising:
a gate oxide layer formed between the gate of the NMOS capacitor and the semiconductor substrate.

9. The decoupling capacitor unit of claim 7, wherein the second cylinder capacitor comprises:
a second bottom electrode connected to the gate of the NMOS capacitor;
a second dielectric layer formed over the second bottom electrode; and
a top electrode formed over the second dielectric layer, wherein the first and second cylinder capacitors are connected in series via the top electrode.

10. The decoupling capacitor unit of claim 9, further comprising:
a second metal interconnection configured to connect the second bottom electrode and the gate of the NMOS capacitor.

11. The semiconductor device comprising a decoupling capacitor unit comprising:
first and second capacitors, each of which is connected between a power supply voltage source and a ground voltage source;
first and second cylinder capacitors connected in series between the power supply voltage source and the ground voltage source; and
first and second interconnections, wherein the first capacitor and the first cylinder capacitor are connected via the first interconnection and the second capacitor and the second cylinder capacitor are connected via the second interconnection.

12. The semiconductor device of claim 11, wherein the first capacitor is a PMOS capacitor and the second capacitor is an NMOS capacitor.

13. The semiconductor device of claim 12, wherein the PMOS capacitor is formed over a N-well in a semiconductor substrate, the PMOS capacitor comprising:
a gate formed over the N-well and coupled to the ground voltage;
a gate oxide layer formed between the gate of the PMOS capacitor and the N-well in the semiconductor substrate;
a source formed in the N-well by diffusing an impurity into the N-well and coupled to the power supply voltage; and
a drain formed in the N-well by diffusing an impurity into the N-well and coupled to the power supply voltage.

14. The semiconductor device of claim 13, wherein the first cylinder capacitor comprises:
a first bottom electrode connected to the gate of the PMOS capacitor;
a first dielectric layer formed over the first bottom electrode; and
a top electrode formed over the first dielectric layer, wherein the first and second cylinder capacitors are connected in series via the top electrode.

15. The semiconductor device of claim 12, wherein the NMOS capacitor is formed over a semiconductor substrate, the NMOS capacitor comprising:
a gate formed over the semiconductor substrate and coupled to the power supply voltage;
a gate oxide layer formed between the gate of the NMOS capacitor and the semiconductor substrate;
a source formed in the semiconductor substrate by diffusing an impurity into the semiconductor substrate and coupled to the ground voltage; and
a drain formed in the semiconductor substrate by diffusing an impurity into the semiconductor substrate and coupled to the ground voltage.

16. The semiconductor device of claim 15, wherein the second cylinder capacitor comprises:
a second bottom electrode connected to the gate of the NMOS capacitor;
a second dielectric layer formed over the second bottom electrode; and
a top electrode formed over the second dielectric layer, wherein the first and second cylinder capacitors are connected in series via the top electrode.

17. A method of forming a decoupling capacitor unit, comprising:
forming a first capacitor comprising a first gate and a first source/drain on a semiconductor substrate;
forming a second capacitor comprising a second gate and a second source/drain on the semiconductor substrate;
forming an interlayer dielectric layer over the first and second MOS capacitors;
forming first and second metal interconnections through the interlayer dielectric layer; and
forming cylinder capacitors connected to the first and second MOS capacitors through the first and second metal interconnections respectively.

18. The method of claim 17, wherein forming the cylinder capacitors comprises:
forming a first cylinder capacitor comprising a top electrode, a first dielectric layer, and a first bottom electrode; and
forming a second cylinder capacitor comprising the top electrode, a second dielectric layer, and a second bottom electrode, wherein the first and second capacitors are connected in series via the top electrode.

19. The method of claims 18,
wherein, in the forming of the first cylinder capacitor, the first metal interconnection is connected to the first bottom electrode; and
wherein, in the forming of the second cylinder capacitor, the second metal interconnection is connected to the second bottom electrode.

20. The method of claim 19, wherein the first and second cylinder capacitors are formed of one or more of same material layers in one or more of same processes.
